(19) United States
(12) Patent Application Publication
(10) Pub. No.: US 2008/0258755 A1
(43) Pub. Date: Oct. 23, 2008

(54) Noise Reduction Among Conductors

(75) Inventors: Moises Cases, Austin, TX (US); Daniel N. de Araujo, Cedar Park, TX (US); Bhyrav M. Mutnury, Austin, TX (US); Nam H. Pham, Round Rock, TX (US)

Correspondence Address: IBM (RPS-BLF);c/o BIGGERS & OHANIAN, LLP, P.O. BOX 1469, AUSTIN, TX, 78767-1469, US

(73) Assignee: International Business Machines Incorporated, Armonk, NY (US)

(21) Appl. No.: 11/737,355

(22) Filed: Apr. 19, 2007

(51) Int. Cl. H03K 17/16

(52) U.S. Cl. 326/22; 326/21; 716/2

(57) ABSTRACT

Noise reduction among conductors, the conductors disposed adjacent to one another, the conductors characterized as two or more aggressor conductors and one or more victim conductors, a least two of the aggressor conductors driven with at least two signals that induce unwanted crosstalk upon at least one of the victim conductors, a programmable delay device disposed in a signal path of each of the at least two signals that induce unwanted crosstalk, including programming a delay period into each programmable delay device; receiving, simultaneously at the programmable delay devices, the at least two signals that induce unwanted crosstalk; and transmitting, on two aggressor conductors, the at least two signals that induce unwanted crosstalk, with the at least two signals separated in time by the delay period.

### BACKGROUND OF THE INVENTION

1. Field of the Invention

The field of the invention is data processing, or, more specifically, methods, apparatus, and products for noise reduction among conductors.

2. Description of Related Art

The development of the EDVAC computer system of 1948 is often cited as the beginning of the computer era. Since that time, computer systems have evolved into extremely complicated devices. Today's computers are much more sophisticated than early systems such as the EDVAC. Computer systems typically include a combination of hardware and software components, application programs, operating systems, processors, buses, memory, input/output devices, and so on. As advances in semiconductor processing and computer architecture push the performance of the computer higher and higher, more sophisticated computer software has evolved to take advantage of the higher performance of the hardware, resulting in computer systems today that are much more powerful than just a few years ago.

One of the areas that has seen much improvement is high speed data communications. Such high speed systems are not without problems, however. In computers and communication systems, time correlated noise can add and degrade performance in terms of signal quality among components of such systems. In typical aggressor/victim configurations, the effect of noise coupling is particularly significant when all aggressors switch at the same time. The noise coupling is proportional to the rise time of the pulse, the faster the system speed, the worse the crosstalk, especially for simultaneously-pulsed aggressor signals.

### SUMMARY OF THE INVENTION

Methods, apparatus, and computer program products are disclosed for noise reduction among conductors, the conductors disposed adjacent to one another, the conductors characterized as two or more aggressor conductors and one or more victim conductors, at least two of the aggressor conductors driven with at least two signals that induce unwanted crosstalk upon at least one of the victim conductors, a programmable delay device disposed in a signal path of each of the at least two signals that induce unwanted crosstalk, including programming a delay period into each programmable delay device; receiving, simultaneously at the programmable delay devices, the at least two signals that induce unwanted crosstalk; and transmitting, on two aggressor conductors, the at least two signals that induce unwanted crosstalk, with the at least two signals separated in time by the delay period.

The foregoing and other objects, features and advantages of the invention will be apparent from the following more particular descriptions of exemplary embodiments of the invention as illustrated in the accompanying drawings wherein like reference numbers generally represent like parts of exemplary embodiments of the invention.

### BRIEF DESCRIPTION OF THE DRAWINGS

FIG. 1 sets forth a functional block diagram and schematic illustrating exemplary apparatus for noise reduction among conductors according to embodiments of the present invention.

FIG. 2 sets forth a schematic diagram of an exemplary programmable delay device useful for noise reduction among conductors in accordance with embodiments of the present invention.

FIG. 3 sets forth a flow chart illustrating an exemplary method for noise reduction among conductors according to embodiments of the present invention.

FIG. 4 sets forth a flow chart illustrating a further exemplary method for noise reduction among conductors according to embodiments of the present invention.

FIG. 5 sets forth a flow chart illustrating a further exemplary method for noise reduction among conductors according to embodiments of the present invention.

FIG. 6 sets forth a flow chart illustrating a further exemplary method for noise reduction among conductors according to embodiments of the present invention.

FIGS. 7A and 7B illustrate two exemplary models of noise level on a victim conductor when signals that induce unwanted crosstalk are present on aggressor conductors.

### DETAILED DESCRIPTION OF EXEMPLARY EMBODIMENTS

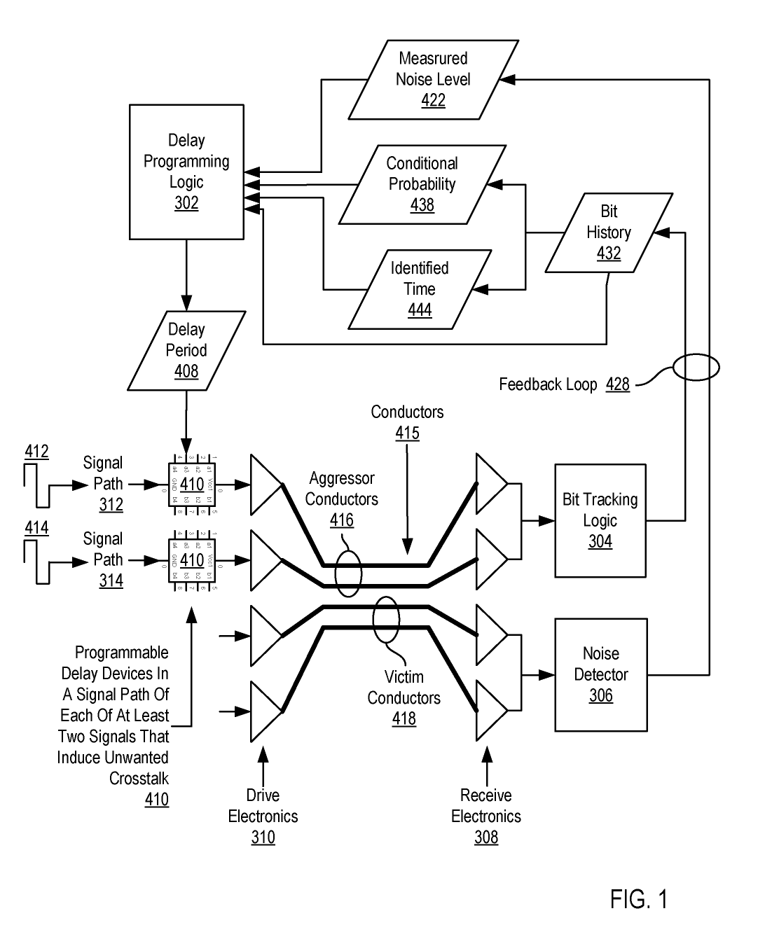

Exemplary methods, systems, and products for noise reduction among conductors according to embodiments of the present invention are described with reference to the accompanying drawings, beginning with FIG. 1. FIG. 1 sets forth a functional block diagram and schematic illustrating exemplary apparatus for noise reduction among conductors according to embodiments of the present invention. The apparatus of FIG. 1 includes a number of conductors (415) disposed adjacent to one another. The conductors (415) are electrical conductors and may be, for example, twisted pairs in a cable, parallel traces on a printed circuit board, conductive pathways etched on substrates inside integrated circuits, and other conductors as will occur to those of skill in the art. The conductors are ‘adjacent’ to one another in that they are near one another in space or position, although the conductors are separated by electrical insulation, as is the case for conductors in twisted-pair cables, traces on printed circuit boards, conductive pathways etched on substrates inside integrated circuits, and so on. The conductors (415) characterized as two aggressor conductors (416) and two victim conductors (418)—although these exact numbers are only for explanation and not a limitation of the present invention. Apparatus that reduces noise among conductors according to embodiments of the present invention typically has at least two aggressor conductors and one or more victim conductors.

The aggressor conductors (416) are driven with at least two signals (412, 414) that induce unwanted crosstalk upon at least one of the victim conductors (418). ‘Crosstalk’ is an unwanted transfer of energy from one conductor to another. Crosstalk typically occurs between adjacent conductors. Crosstalk induced on a victim conductor as an unwanted signal is considered to be a form of noise. Crosstalk on a victim conductor represents an increase in the overall noise level on the victim conductor.

In a given set of conductors, whether a particular conductor is characterized as an aggressor or a victim is a matter of usage. Any conductor that is a source of an unwanted transfer is characterized as an ‘aggressor.’ Any conductor that is the recipient of an unwanted transfer is characterized as a ‘victim.’ If all conductors are driven with signals that induce crosstalk, in a cable or a bus for example, then all the conductors are both aggressors and victims. In the example of FIG. 1, for convenience of explanation, only two conductors (416) of the four conductors (415) depicted are characterized as aggressors, and only two (418) of the four conductors depicted are characterized as victims. This is, however, only for ease of explanation. Readers will recognize that as a practical matter, when four such conductors are implemented as twisted pairs in a cable or as four conductive traces of a bus on a printed circuit board for example, all four of the conductors then typically will be driven with signals that induce unwanted crosstalk, all four conductors then would be correctly characterized as aggressors, and all four conductors then would be correctly characterized as victims.

The example apparatus of FIG. 1 includes a programmable delay device (410) disposed in a signal path (312, 314) of each of the signals (312, 314) that induce unwanted crosstalk. The apparatus of FIG. 1 also includes delay programming logic (302) and drive electronics (310). The delay programming logic (302) is a module of logic circuitry, sequential or non-sequential, optionally including a computer processor and memory containing a control program, that is configured to program a delay period (408) into each the programmable delay device (410). The programmable delay devices (410) receive simultaneously the signals (412, 414) that induce unwanted crosstalk. The programmable delay device (410) inserts a delay period, in effect a phase shift, between the incoming signals, and the drive electronics (310) transmits, on two aggressor conductors, the two signals (412, 414) that induce unwanted crosstalk with the two signals separated in time by the delay period. The drive electronics (310) are shown here driving the conductors in a single-ended fashion, but readers will recognize that the drive electronics can drive differentially as well, and in other ways as will occur to those of skill in the art.

The apparatus of FIG. 1 also includes a noise detector (306) that measures the noise level on a victim conductor (418) when the two signals (412, 414) that induce unwanted crosstalk are present on the aggressor conductors (416). The noise level so measured (422) includes general background noise, thermal noise, other noise, as well as noise induced as unwanted crosstalk from the aggressor conductors (416). In the example of FIG. 1, the noise detector provides the measured noise level to the delay programming logic (302) through a feedback loop (428), and the delay programming logic, in programming the delay period (408), can program a delay period (408) into each programmable delay device (410) in dependence upon the measured noise level (422). Programming delay between aggressor signals in dependence upon a measured noise level from a victim conductor typically means adjusting the delay to minimize the noise level. The delay programming logic (302) can, for example, be programmed to increase the delay period (408), thereby reducing the crosstalk in particular and the noise level generally, until the measured noise level (422) decreases below a predefined threshold.

In the example of FIG. 1, the signals (412, 414) that induce unwanted crosstalk can be digital signals representing bits of digital data, 1s and 0s. The example apparatus of FIG. 1 includes a module of bit tracking logic, a module of logic circuitry, sequential or non-sequential, optionally including a computer processor and memory containing a control program, that is configured to maintain a bit history (432) for each of the signals (312, 314) that induce unwanted crosstalk. The bit tracking logic (304) can provide the bit history (432) to the delay programming logic (302) through feedback loop (428). The delay programming logic can program a delay period (408) into each programmable delay device (410) in dependence upon the bit history (432).

Given a bit history (432) of a signal (412, 414) that induces unwanted crosstalk, either the delay programming logic (302) or the bit tracking logic (304) can be programmed to calculate a conditional probability (438) of an occurrence of a signal transition representing a bit. High speed transmission protocols typically represent changes in bit values with transitions in signal level, so that a change from a 0 to a 1 is indicated with a change in signal level, then if the next bit is also a 1, that fact is represented by leaving the signal level unchanged during the next clock period. When a string of 1s follows such a transition, the signal level remains the same until the next 0 appears in the signal, and the 0 is then represented by a change in signal level. If the next bit value is a 0, the signal level remains unchanged. If the next bit is a 1, that fact is represented by a transition in signal level, and so on.

Increasingly long strings of the same bit value have decreasing conditional probabilities. The probability that any particular bit is a 1 is ½. The conditional probability of two Is in sequence is ½×½=¼. The conditional probability of three Is in sequence is ½×½×½=⅛. And so on. Long strings of the same bit value represent periods of time with fewer signal transitions and reduced risk of inducing unwanted crosstalk. Increasingly long strings of bits with the same value, however, are increasingly improbable. The delay programming logic (302) therefore can be programmed to dynamically alter the delay period during transmission of signals by, for example, increasing the delay period (408), thereby reducing the risk of crosstalk, as the conditional probability (438) of a sequence of bits with the same value decreases.

In the example of FIG. 1, the signals (412, 414) that induce unwanted crosstalk can be digital signals representing bits of digital data, 1s and 0s, and the drive electronics (310) can transmit the signals that induce unwanted crosstalk according to a communications protocol that limits bits of a same value. Examples of communications protocols that limit bits of a same value include the HyperTransport protocol, the PCI Express protocol, the IEEE 1394b protocol, the Serial ATA protocol, the Serial Attached SCSI (‘SAS’) protocol, the Fibre Channel protocol, the Serial Storage Architecture (‘SSA’) protocol, the Gigabit Ethernet protocol, the InfiniBand protocol, and the Serial RapidIO protocol. Such protocols typically limit bits of a same value with an encoding format such as, for example, an ‘8b/10b’ encoding format. Such an encoding carries an encoded clock signal and maps 8-bit symbols to 10-bit symbols to achieve DC-balance with bounded disparity, while providing enough state changes to allow reasonable clock recovery. This means that there are just as many 1s as 0s in a string of two symbols, and that there are not too many 1s or 0s in a row. This encoding also helps reduce intersymbol interference in high speed signals. 8b/10b encoding limits strings of bits of the same value to no more than five.

Given a bit history (432) of a signal (412, 414) that induces unwanted crosstalk and a communications protocol that limits bits of a same value, either the delay programming logic (302) or the bit tracking logic (304) can be programmed to identify in dependence upon the bit history and the communications protocol a time when a signal transition representing a bit will occur. In all protocols that encode according to 8b/10b, for example, a signal transition will always occur after a string of five 1s. And in protocols that encode according to 8b/10b, a signal transition will always occur after a string of five 0s. Each of these is an example of an identified time (444) when a signal transition representing a bit will occur. The delay programming logic (302) therefore can be programmed to dynamically alter the delay period during transmission of signals by, for example, increasing the delay period (408), thereby reducing the risk of crosstalk, at an identified time (444) when a signal transition representing a bit will occur.

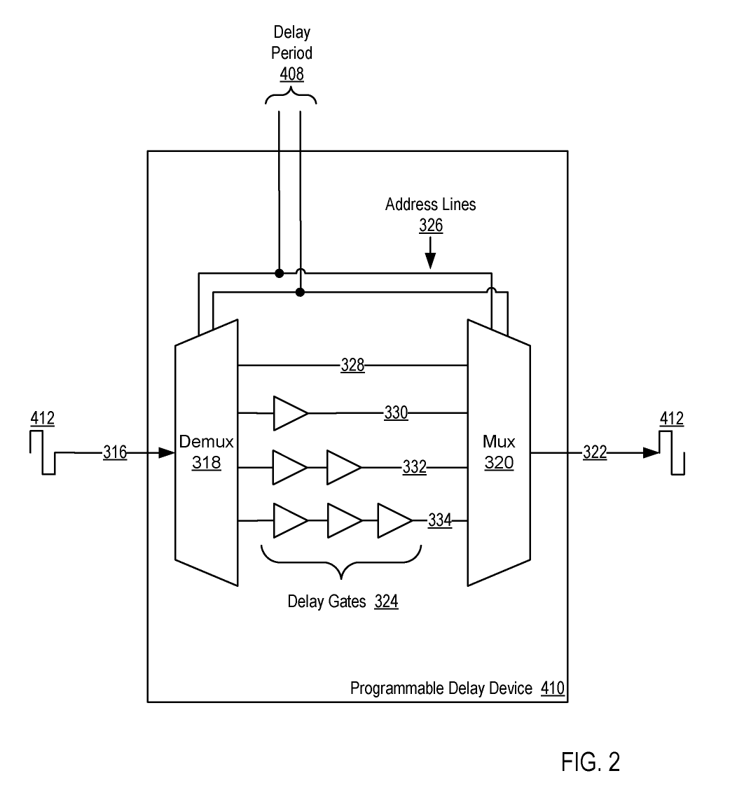

For further explanation, FIG. 2 sets forth a schematic diagram of an exemplary programmable delay device (410) useful for noise reduction among conductors in accordance with embodiments of the present invention. The example programmable delay device (410) of FIG. 2 is composed of a demultiplexer (318) and a multiplexer (320) with a number of delay gates (324) connected between them. The delay gates (324) are configured to provide four delay lines (328, 330, 332, 334) representing respectively delay periods of zero gate delays (328), one gate delay (330), two gate delays (332), and three gate delays (334). A gate delay is selected by the delay period (408) driven by delay programming logic (302 on FIG. 1) as a digital value onto the address lines (326) of both the demultiplexer (318) and the multiplexer (320). The programmable delay device (410) receives on its input (316) a signal (412) that induces unwanted crosstalk and presents on its output (322) the same signal delayed with respect to its arrival time by zero, one, two, or three gate delays depending on the value of the delay period (408). The four values of delay depicted here, zero, one, two, or three gate delays, are for explanation only, not a limitation of the present invention. Programmable delay devices useful for noise reduction among conductors in accordance with embodiments of the present invention can be implemented with any number of delay values as may occur to those of skill in the art.

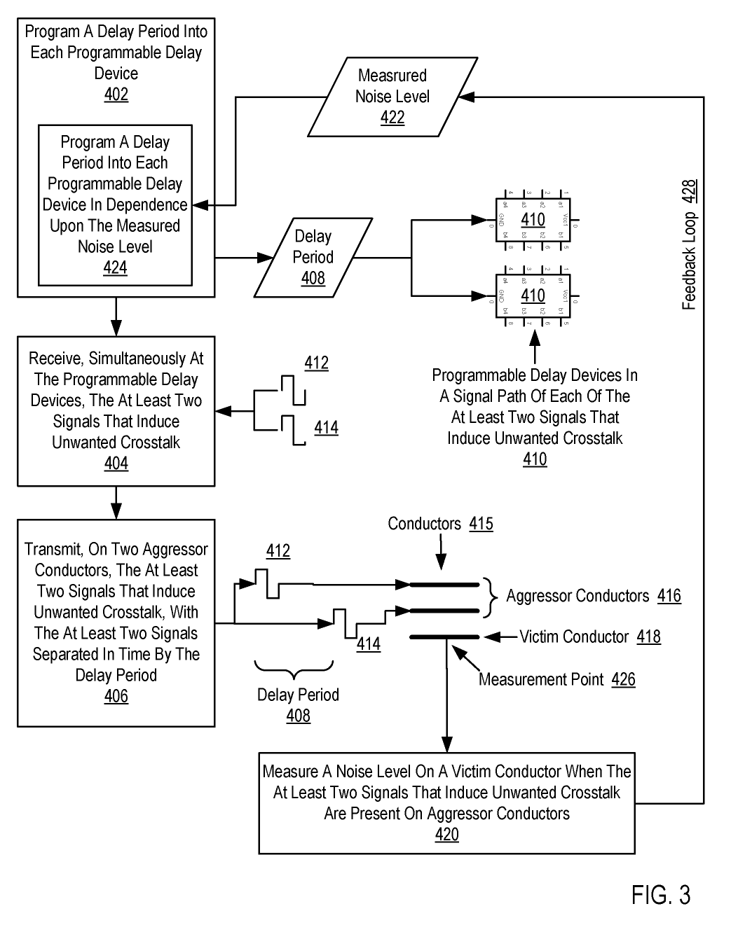

For further explanation, FIG. 3 sets forth a flow chart illustrating an exemplary method for noise reduction among conductors according to embodiments of the present invention. The method of FIG. 3 is for implementation with apparatus similar to those described above with reference to FIGS. 1 and 2: a plurality of conductors (415), the conductors disposed adjacent to one another, the conductors characterized as two or more aggressor conductors (416) and one or more victim conductors (418), at least two of the aggressor conductors driven with at least two signals (412, 414) that induce unwanted crosstalk upon at least one of the victim conductors, with a programmable delay device (410) disposed in a signal path of each of the signals that induce unwanted crosstalk. The method of FIG. 3 includes programming (402) a delay period (408) into each programmable delay device (410), receiving (404), simultaneously at the programmable delay devices, the at least two signals (412, 414) that induce unwanted crosstalk, and transmitting (406), on two aggressor conductors (416), the at least two signals (412, 414) that induce unwanted crosstalk, with the at least two signals separated in time by the delay period (408). The method of FIG. 3 also includes measuring (420), at a measurement point (426) on a victim conductor (418), a noise level on a victim conductor when the signals (412, 414) that induce unwanted crosstalk are present on aggressor conductors (416), and providing the measured noise level (422) from the measurement point to the delay programming function (402) through a feedback loop (428). In the method of FIG. 3, programming (402) a delay period includes programming (424) a delay period into each programmable delay device in dependence upon the measured noise level (422).

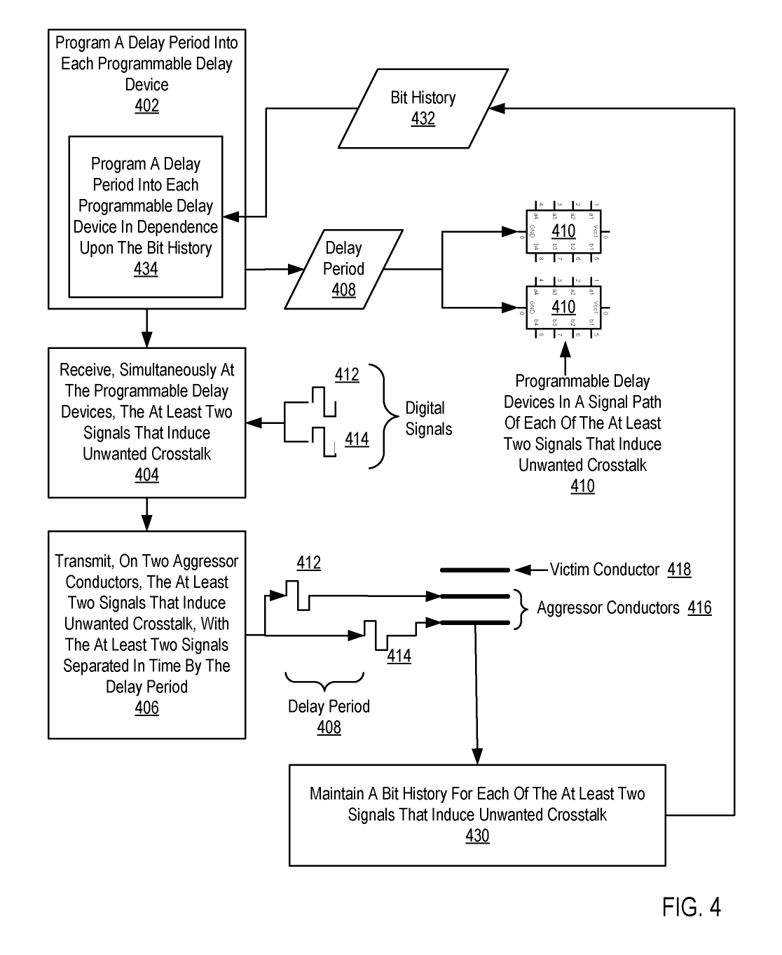

For further explanation, FIG. 4 sets forth a flow chart illustrating a further exemplary method for noise reduction among conductors according to embodiments of the present invention. The method of FIG. 4 is similar to the method of FIG. 3, including as it does programming (402) a delay period (408) into each programmable delay device (410), receiving (404), simultaneously at the programmable delay devices, the at least two signals (412, 414) that induce unwanted crosstalk, and transmitting (406), on two aggressor conductors (416), the at least two signals (412, 414) that induce unwanted crosstalk, with the at least two signals separated in time by the delay period (408)—all of which functions in a similar manner as described above with reference to FIGS. 1, 2, and 3. In the method of FIG. 4, however, the signals (412, 414) that induce unwanted crosstalk are digital signals representing bits of digital data, the method of FIG. 4 includes maintaining (430) a bit history for each of the signals (412, 414) that induce unwanted crosstalk. In the method of FIG. 4, programming (402) a delay period (408) includes programming (434) a delay period into each programmable delay device (410) in dependence upon the bit history (432).

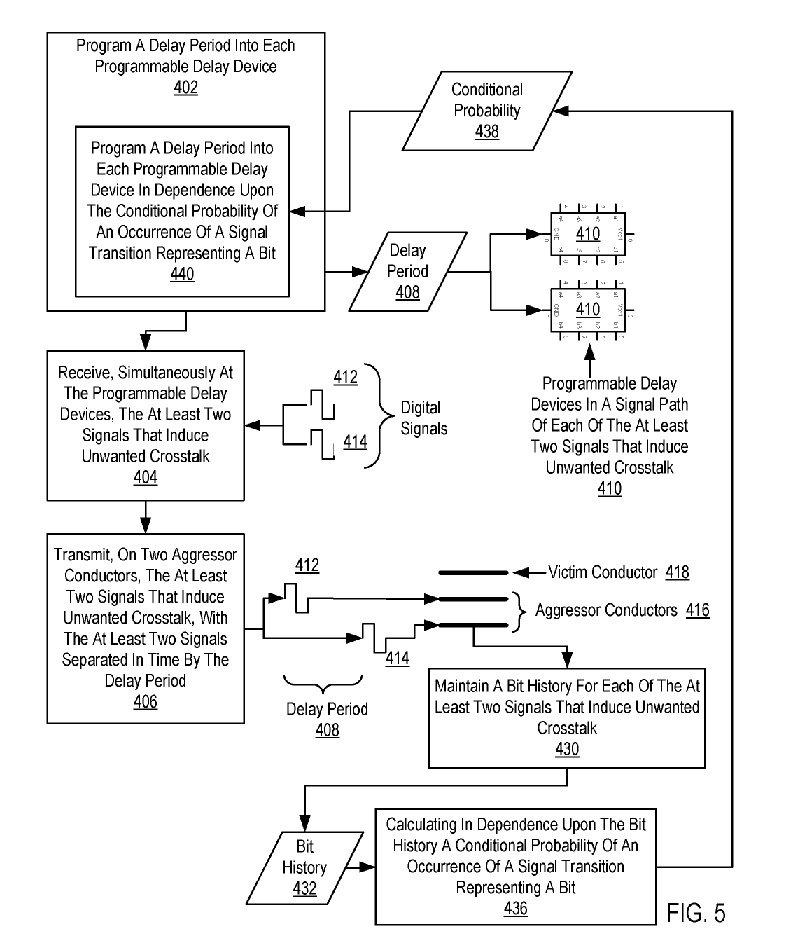

For further explanation, FIG. 5 sets forth a flow chart illustrating a further exemplary method for noise reduction among conductors according to embodiments of the present invention. The method of FIG. 5 is similar to the method of FIG. 3, including as it does programming (402) a delay period (408) into each programmable delay device (410), receiving (404), simultaneously at the programmable delay devices, the at least two signals (412, 414) that induce unwanted crosstalk, and transmitting (406), on two aggressor conductors (416), the at least two signals (412, 414) that induce unwanted crosstalk, with the at least two signals separated in time by the delay period (408)—all of which functions in a similar manner as described above with reference to FIGS. 1, 2, and 3. In the method of FIG. 5, however, the signals (412, 414) that induce unwanted crosstalk are digital signals representing bits of digital data, and the method of FIG. 5 includes maintaining (430) a bit history (432) for each of the signals that induce unwanted crosstalk. The method of FIG. 5 also includes calculating (436) in dependence upon the bit history (432) a conditional probability of an occurrence of a signal transition representing a bit. In the method of FIG. 5, programming (402) a delay period (408) includes programming (440) a delay period (408) into each programmable delay device (410) in dependence upon the conditional probability (438).

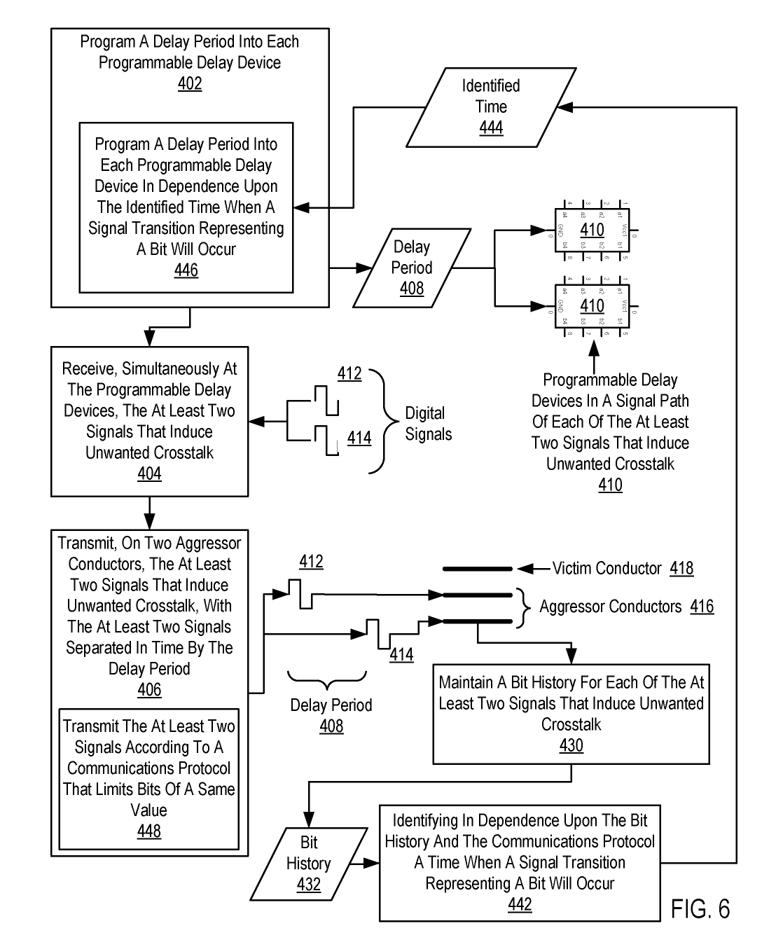

For further explanation, FIG. 6 sets forth a flow chart illustrating a further exemplary method for noise reduction among conductors according to embodiments of the present invention. The method of FIG. 6 is similar to the method of FIG. 3, including as it does programming (402) a delay period (408) into each programmable delay device (410), receiving (404), simultaneously at the programmable delay devices, the at least two signals (412, 414) that induce unwanted crosstalk, and transmitting (406), on two aggressor conductors (416), the at least two signals (412, 414) that induce unwanted crosstalk, with the at least two signals separated in time by the delay period (408)—all of which functions in a similar manner as described above with reference to FIGS. 1, 2, and 3. In the method of FIG. 6, however, the signals (412, 414) that induce unwanted crosstalk are digital signals representing bits of digital data, and transmitting (406) the signals that induce unwanted crosstalk includes transmitting the signals according to a communications protocol that limits bits of a same value. The method of FIG. 6 also includes maintaining (430) a bit history (432) for each of the signals that induce unwanted crosstalk and identifying (442) in dependence upon the bit history and the communications protocol a time (444) when a signal transition representing a bit will occur. In the method of FIG. 6, programming (402) a delay period (408) includes programming (446) a delay period (408) into each programmable delay device (410) in dependence upon the identified time (444) when a signal transition representing a bit will occur.

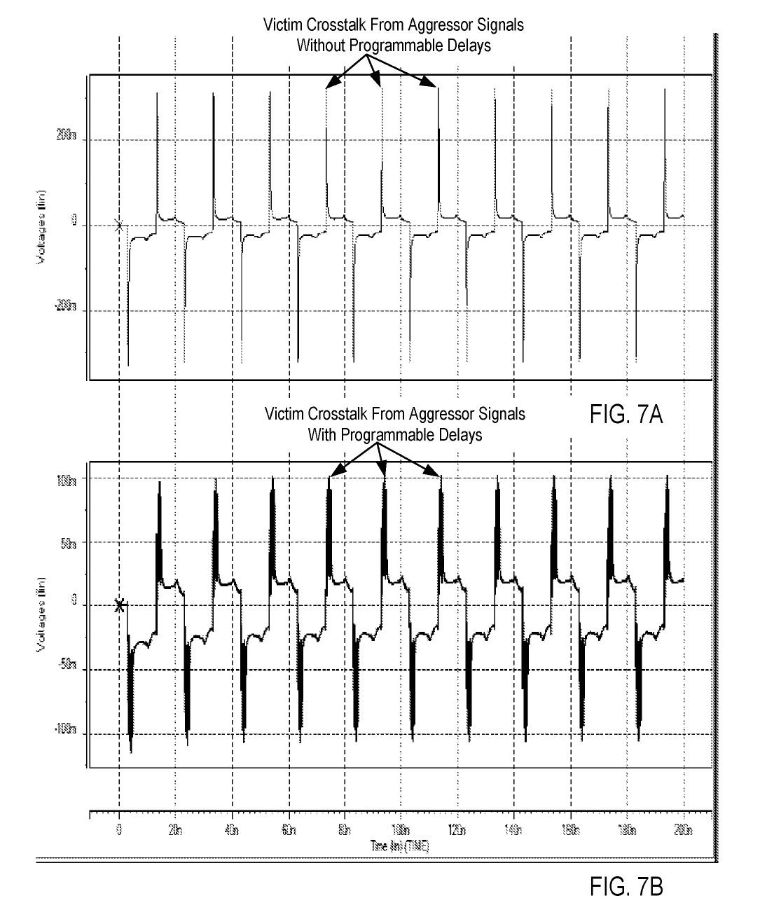

For further explanation, FIGS. 7A and 7B illustrate two exemplary models of noise level on a victim conductor when signals that induce unwanted crosstalk are present on aggressor conductors. FIGS. 7A and 7B illustrate some of the advantages of noise reduction among conductors according to embodiments of the present invention. FIG. 7A depicts an exemplary model of noise level on a victim conductor when signals that induce unwanted crosstalk are driven onto the aggressor conductors with no delay period or phase shift among the aggressor signals. The induced victim crosstalk in the example of FIG. 7A shows peak values of approximately −250 millivolts and +250 millivolts. FIG. 7B depicts an exemplary model of noise level on a victim conductor when the same aggressors are driven onto the aggressor conductors with a delay period or phase shift programmed among the aggressor signals according to embodiments of the present invention. The induced victim crosstalk in the example of FIG. 7A shows peak values of approximately −100 millivolts and +100 millivolts—a substantial noise reduction among conductors achieved in accordance with an embodiment of the present invention. In view of these explanations, readers will appreciate that benefits of noise reduction among conductors according to embodiments of the present invention include not only the improved signal quality from the noise reduction itself, but also, an ability to route conductors closer together while maintaining the same noise coupling, resulting in reduction in layers in packages and printed circuit boards.

Exemplary embodiments of the present invention are described largely in the context of a fully functional computer system for noise reduction among conductors. Readers of skill in the art will recognize, however, that the present invention also may be embodied in a computer program product disposed on signal bearing media for use with any suitable data processing system. Such signal bearing media may be transmission media or recordable media for machine-readable information, including magnetic media, optical media, or other suitable media. Examples of recordable media include magnetic disks in hard drives or diskettes, compact disks for optical drives, magnetic tape, and others as will occur to those of skill in the art. Examples of transmission media include telephone networks for voice communications and digital data communications networks such as, for example, Ethernets™ and networks that communicate with the Internet Protocol and the World Wide Web as well as wireless transmission media such as, for example, networks implemented according to the IEEE 802.11 family of specifications. Persons skilled in the art will immediately recognize that any computer system having suitable programming means will be capable of executing the steps of the method of the invention as embodied in a program product. Persons skilled in the art will recognize immediately that, although some of the exemplary embodiments described in this specification are oriented to software installed and executing on computer hardware, nevertheless, alternative embodiments implemented as firmware or as hardware are well within the scope of the present invention.

It will be understood from the foregoing description that modifications and changes may be made in various embodiments of the present invention without departing from its true spirit. The descriptions in this specification are for purposes of illustration only and are not to be construed in a limiting sense. The scope of the present invention is limited only by the language of the following claims.

What is claimed is:

1. A method of noise reduction among conductors, the conductors disposed adjacent to one another, the conductors characterized as two or more aggressor conductors and one or more victim conductors, at least two of the aggressor conductors driven with at least two signals that induce unwanted crosstalk upon at least one of the victim conductors, a programmable delay device disposed in a signal path of each of the at least two signals that induce unwanted crosstalk, the method comprising:
programming a delay period into each programmable delay device;
receiving, simultaneously at the programmable delay devices, the at least two signals that induce unwanted crosstalk; and
transmitting, on two aggressor conductors, the at least two signals that induce unwanted crosstalk, with the at least two signals separated in time by the delay period.

2. The method of claim 1 further comprising:
measuring a noise level on a victim conductor when the at least two signals that induce unwanted crosstalk are present on aggressor conductors;
wherein programming a delay period further comprises programming a delay period into each programmable delay device in dependence upon the measured noise level.

3. The method of claim 1 further comprising:
measuring, at a measurement point on a victim conductor, a noise level on the victim conductor when the at least two signals that induce unwanted crosstalk are present on aggressor conductors; and
providing the measured noise level from the measurement point through a feedback loop;
wherein programming a delay period further comprises programming a delay period into each programmable delay device in dependence upon the measured noise level.

4. The method of claim 1 wherein the at least two signals that induce unwanted crosstalk comprise digital signals representing bits of digital data, and the method further comprises:
maintaining a bit history for each of the at least two signals that induce unwanted crosstalk, wherein programming a delay period further comprises programming a delay period into each programmable delay device in dependence upon the bit history.

5. The method of claim 1 wherein the at least two signals that induce unwanted crosstalk comprise digital signals representing bits of digital data, and the method further comprises:
maintaining a bit history for each of the at least two signals that induce unwanted crosstalk; and
calculating in dependence upon the bit history a conditional probability of an occurrence of a signal transition representing a bit;
wherein programming a delay period further comprises programming a delay period into each programmable delay device in dependence upon the conditional probability.

6. The method of claim 1 wherein:
the at least two signals that induce unwanted crosstalk comprise digital signals representing bits of digital data;
transmitting the at least two signals that induce unwanted crosstalk further comprises transmitting the at least two signals according to a communications protocol that limits bits of a same value;
and the method further comprises:
maintaining a bit history for each of the at least two signals that induce unwanted crosstalk; and
identifying in dependence upon the bit history and the communications protocol a time when a signal transition representing a bit will occur;
wherein programming a delay period further comprises programming a delay period into each programmable delay device in dependence upon the identified time when a signal transition representing a bit will occur.

7. Apparatus for noise reduction among conductors, the apparatus comprising:
conductors disposed adjacent to one another, the conductors characterized as two or more aggressor conductors and one or more victim conductors, at least two of the aggressor conductors driven with at least two signals that induce unwanted crosstalk upon at least one of the victim conductors, with a programmable delay device disposed in a signal path of each of the at least two signals that induce unwanted crosstalk, the apparatus further comprising delay programming logic and drive electronics, the apparatus capable of:
programming by the delay programming logic a delay period into each programmable delay device;
receiving, simultaneously at the programmable delay devices, the at least two signals that induce unwanted crosstalk; and
transmitting by the drive electronics, on two aggressor conductors, the at least two signals that induce unwanted crosstalk, with the at least two signals separated in time by the delay period.

8. The apparatus of claim 7 further comprising a noise detector and a feedback loop connecting the noise detector to the delay programming logic, the apparatus further capable of:
measuring by the noise detector a noise level on a victim conductor when the signals that induce unwanted crosstalk are present on aggressor conductors;
wherein programming a delay period further comprises programming a delay period into each programmable delay device in dependence upon the measured noise level.

9. The apparatus of claim 7 further comprising a noise detector and a feedback loop connecting the noise detector to the delay programming logic, the apparatus further capable of:
measuring by the noise detector, at a measurement point on a victim conductor, a noise level on the victim conductor when the at least two signals that induce unwanted crosstalk are present on aggressor conductors; and
providing by the noise detector the measured noise level from the measurement point to the delay programming logic through a feedback loop;
wherein programming a delay period further comprises programming a delay period into each programmable delay device in dependence upon the measured noise level.

10. The apparatus of claim 7 wherein the at least two signals that induce unwanted crosstalk comprise digital signals representing bits of digital data, the apparatus further comprises bit tracking logic and a feedback loop connecting the bit tracking logic to the delay programming logic, and the apparatus is further capable of:
maintaining by the bit tracking logic a bit history for each of the signals that induce unwanted crosstalk, wherein programming a delay period further comprises programming a delay period into each programmable delay device in dependence upon the bit history.

11. The apparatus of claim 7 wherein the at least two signals that induce unwanted crosstalk comprise digital signals representing bits of digital data, the apparatus further comprises bit tracking logic and a feedback loop connecting the bit tracking logic to the delay programming logic, and the apparatus is further capable of:
maintaining by the bit tracking logic a bit history for each of the at least two signals that induce unwanted crosstalk; and
calculating in dependence upon the bit history a conditional probability of an occurrence of a signal transition representing a bit;
wherein programming a delay period further comprises programming a delay period into each programmable delay device in dependence upon the conditional probability.

12. The apparatus of claim 7 wherein the at least two signals that induce unwanted crosstalk comprise digital signals representing bits of digital data, transmitting the at least two signals that induce unwanted crosstalk further comprises transmitting the at least two signals according to a communications protocol that limits bits of a same value, the apparatus further comprises bit tracking logic and a feedback loop connecting the bit tracking logic to the delay programming logic, and the apparatus is further capable of:
maintaining by the bit tracking logic a bit history for each of the at least two signals that induce unwanted crosstalk; and
identifying in dependence upon the bit history and the communications protocol a time when a signal transition representing a bit will occur;
wherein programming a delay period further comprises programming a delay period into each programmable delay device in dependence upon the identified time when a signal transition representing a bit will occur.

13. A computer program product for noise reduction among conductors, the conductors disposed adjacent to one another, the conductors characterized as two or more aggressor conductors and one or more victim conductors, at least two of the aggressor conductors driven with at least two signals that induce unwanted crosstalk upon at least one of the victim conductors, a programmable delay device disposed in a signal path of each of the at least two signals that induce unwanted crosstalk, the computer program product disposed upon a computer readable, signal bearing medium, the computer program product comprising computer program instructions capable of:
programming a delay period into each programmable delay device;
receiving, simultaneously at the programmable delay devices, the at least two signals that induce unwanted crosstalk; and
transmitting, on two aggressor conductors, the at least two signals that induce unwanted crosstalk, with the at least two signals separated in time by the delay period.

14. The computer program product of claim 13 wherein the signal bearing medium comprises a recordable medium.

15. The computer program product of claim 13 wherein the signal bearing medium comprises a transmission medium.

16. The computer program product of claim 13 further comprising computer program instructions capable of:
measuring a noise level on a victim conductor when the at least two signals that induce unwanted crosstalk are present on aggressor conductors;
wherein programming a delay period further comprises programming a delay period into each programmable delay device in dependence upon the measured noise level.

17. The computer program product of claim 13 further comprising computer program instructions capable of:
measuring, at a measurement point on a victim conductor, a noise level on the victim conductor when the at least two signals that induce unwanted crosstalk are present on aggressor conductors; and
providing the measured noise level from the measurement point through a feedback loop;
wherein programming a delay period further comprises programming a delay period into each programmable delay device in dependence upon the measured noise level.

18. The computer program product of claim 13 wherein the at least two signals that induce unwanted crosstalk comprise digital signals representing bits of digital data, and the computer program product further comprises computer program instructions capable of:
maintaining a bit history for each of the at least two signals that induce unwanted crosstalk, wherein programming a delay period further comprises programming a delay period into each programmable delay device in dependence upon the bit history.

19. The computer program product of claim 13 wherein the at least two signals that induce unwanted crosstalk comprise digital signals representing bits of digital data, and the computer program product further comprises computer program instructions capable of:
maintaining a bit history for each of the at least two signals that induce unwanted crosstalk; and
calculating in dependence upon the bit history a conditional probability of an occurrence of a signal transition representing a bit;
wherein programming a delay period further comprises programming a delay period into each programmable delay device in dependence upon the conditional probability.

20. The computer program product of claim 13 wherein the at least two signals that induce unwanted crosstalk comprise digital signals representing bits of digital data, transmitting the at least two signals that induce unwanted crosstalk further comprises transmitting the at least two signals according to a communications protocol that limits bits of a same value, and the computer program product further comprises computer program instructions capable of:
maintaining a bit history for each of the at least two signals that induce unwanted crosstalk; and
identifying in dependence upon the bit history and the communications protocol a time when a signal transition representing a bit will occur;
wherein programming a delay period further comprises programming a delay period into each programmable delay device in dependence upon the identified time when a signal transition representing a bit will occur.
